(19) United States
(12) Patent Application Publication
(10) Pub. No.: US 2005/0263883 A1
(43) Pub. Date: Dec. 1, 2005

(54) Asymmetric bump structure

(75) Inventors: Tong-Hong Wang, Banting (MY); Yi-Shao Lai, Taipei (TW); Jeng-Da Wu, Kaohsiung City (TW)

Correspondence Address: GENESIS/GENUS LAW GROUP, 12760 HIGH BLUFF DRIVE, SUITE 300, SAN DIEGO, CA, 92130, US

(73) Assignee: Advance Semiconductor Engineering Inc.

(21) Appl. No.: 11/134,223

(22) Filed: May 20, 2005

(30) Foreign Application Priority Data
May 26, 2004 (TW) 93114940

(51) Int. Cl. H01L 23/48

(52) U.S. Cl. 257/737; 257/738

(57) ABSTRACT

An asymmetric bump structure for wafer is provided. First, the wafer includes multi-chip units each of which has an active surface. The asymmetric bump structure includes a conductive surface on the active surface, a conductive structure contacted the portion of the conductive surface and located on the both conductive surface and the active surface, and a conductive material contacted the conductive structure. The conductive material and the conductive structure contacted part of the conductive surface have respective geometric centers which are not on an identical vertical axis.

### BACKGROUND OF THE INVENTION

1. Field of the Invention

The invention relates generally to a conductive structure of semiconductor manufacture. In particular, the invention relates to an asymmetric conductive bump.

2. Description of the Prior Art

The technology of wafer bump relates to forming metal bumps made of gold or tin lead alloy on the bonding pads of the chip. When melt by heat, the metal bumps are configured for jointing the chip and the substrate. Such a jointing method not only reduces the volume of ICs and cost, but also improves the connection density and performance of heat dissipation.

FIG. 1 is a schematic cross-sectional diagram in company with a corresponding top-side diagram illustrating a conductive bump structure in accordance with the prior art. A metal pad 101 is formed on a wafer 100, such as an aluminum pad, by any suitable semiconductor method. A passivation layer 102 covers the wafer 100 and the partial surface of the metal pad 101. Next, an under bump metallurgy structure 103 is formed on the exposed metal pad 101. Typically, the under bump metallurgy structure 103 is a symmetric structure relative to the exposed metal pad 101. Thus, a conductive bump (not shown) defined by and on the under bump metallurgy structure 103 is also a symmetric structure relative to the exposed metal pad 101.

Referring to the top-side diagram of FIG. 1, the under bump metallurgy structure 103 is made up of the first region 106 and the second region 105. The first region 106 is the portion of the under bump metallurgy structure 103 contacting the metal pad 101. On the other hand, the second region 105 is the portion of the under bump metallurgy structure 103 not contacting the metal pad 101. Furthermore, a horizontal axis 107 and a vertical axis 108 illustrate the symmetric structure as follows. The horizontal axis 107 and the vertical axis 108 are perpendicular to each other at the center of the exposed metal pad 101, and further divide the under bump metallurgy structure 103 into the equal regions: the first region 106 and the second region 105. In other words, the centers of the circles of the first region 106 and the second region 105 respectively overlap the intersection of the horizontal axis 107 and the vertical axis 108.

Accordingly, it is possible to cause cracking after the repeating heat cycles in the process. The cracks may propagate in the symmetric structure of the under bump metallurgy structure 103 to cause a broken circuit and connection failure between the chip and an exterior circuit. Hence, the complex circuit in the chip malfunctions completely.

### SUMMARY OF THE INVENTION

Accordingly, a conductive bump structure is provided to have an asymmetric structure with two centers not overlapped. The conductive layer on the passivation layer is an asymmetric structure.

Further, an asymmetric-shaped conductive bump is provided to pass more current, and improve heat dissipation and reliability.

An asymmetric bump structure is applied on a wafer that includes a plurality of chip units each of which has an active surface. The asymmetric bump structure includes a conductive surface, a conductive structure, and a conductive material. The conductive surface is on the active surface. The conductive structure contacts a portion of the conductive surface and is positioned on both the conductive surface and the active surface. The conductive material contacts the conductive structure, and the geometric centers of the conductive material and the contacted portion of the conductive surface are not on an identical vertical line.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic cross-sectional diagram illustrating a conventional bump structure; and

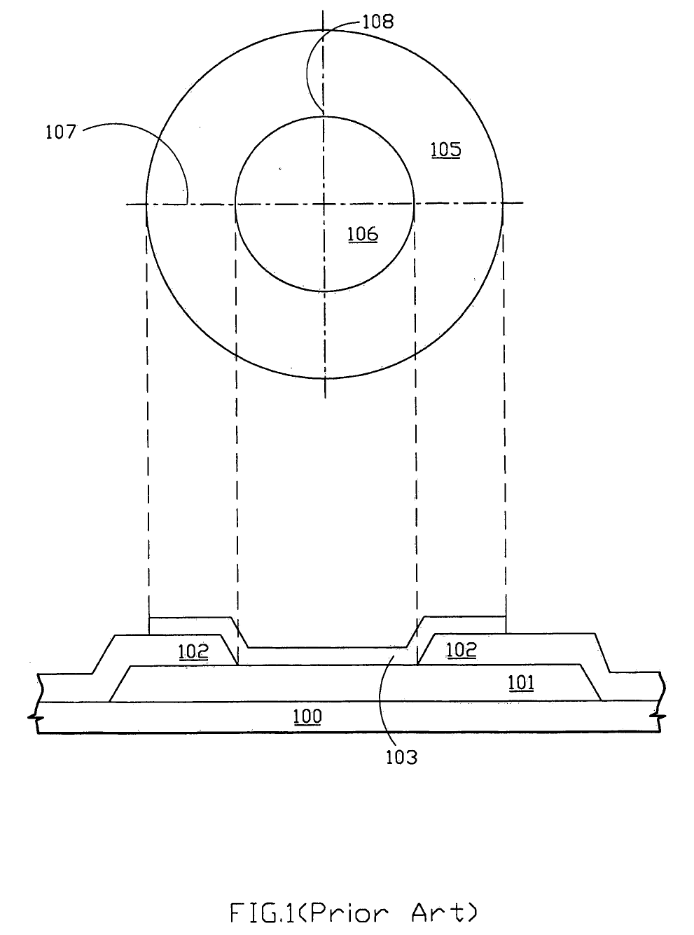

FIG. 2 is a schematic cross-sectional diagram illustrating an embodiment in accordance with the present invention.

### DESCRIPTION OF THE PREFERRED EMBODIMENTS

Before describing the invention in detail, a brief discussion of some underlying concepts will first be provided to facilitate a complete understanding of the invention.

An asymmetric bump structure is applied on a wafer that includes a plurality of chip units each of which has an active surface. The asymmetric bump structure includes a conductive surface, a conductive structure, and a conductive material. The conductive surface is on the active surface. The conductive structure contacts a portion of the conductive surface and is positioned on both the conductive surface and the active surface. The conductive material contacts the conductive structure, and the geometric centers of the conductive material and the contacted portion of the conductive surface are not on an identical vertical line.

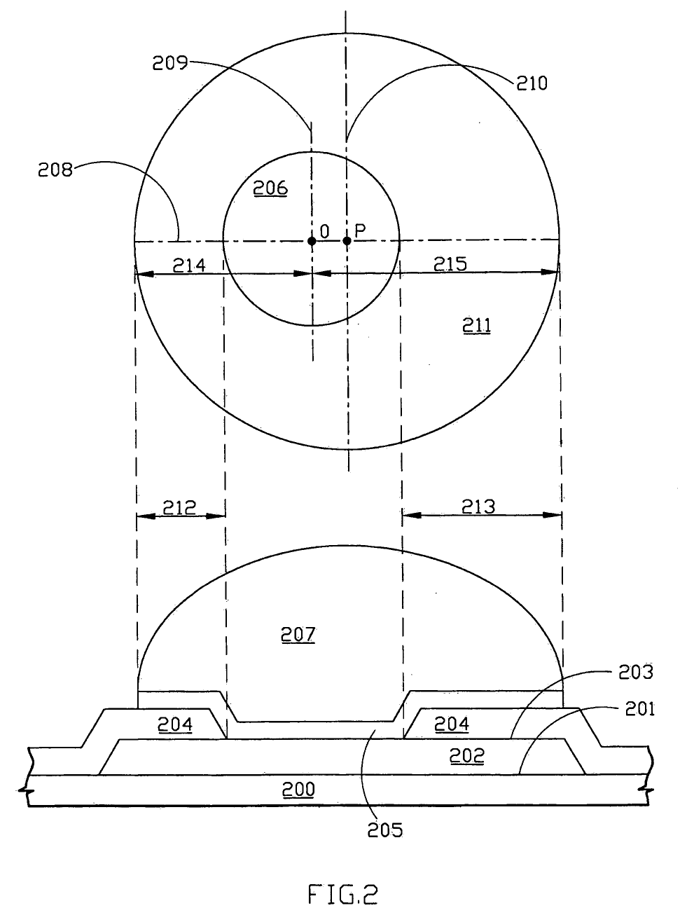

FIG. 2 shows a schematic cross-sectional diagram in company with a corresponding top-side diagram illustrating a conductive bump structure in accordance with the present invention. As shown in FIG. 2, a wafer includes multitudes of chip units 200 each of which has an active surface 201. A conductive surface 203 is formed on the active surface 201. A conductive structure 205 contacts a portion of the conductive surface 203 and is positioned on the conductive surface 203 and the active surface 201. Finally, a conductive material 207 contacts the conductive structure 205, and the conductive structure 205 together with the conductive material 207 constitute an asymmetric structure. That is, the geometric centers of the conductive material 207 and the portion of the conductive surface 203 contacting the conductive structure 205 are not on an identical vertical line. Furthermore. A passivation layer 204 covering and contacting a portion of the conductive surface 203 can be formed before the formation of the conductive structure 205.

In one embodiment, the wafer comprises a silicon wafer, but is not limited to a silicon wafer, or a silicon wafer with conductive pads and a redistribution layer electrically connecting the conductive pads. The conductive pads comprise metal pads, such as aluminum pads 202 shown in FIG. 2. Furthermore, the conductive surface 203 can be the top surface of the metal pad or consists of the redistribution layer. Next, the passivation layer 204 comprises a dielectric layer, such as a silicon nitride or a polymer layer. By any suitable method, the passivation layer 204 is partially removed to form one or more openings for exposing a portion of the conductive surface 203 (this portion of the conductive surface 203 refers as the first surface 206 hereafter). Moreover, the shape of the conductive material 207 is subject to the conductive structure 205. That is to say, the shape of the conductive structure 205 determines the shape of the conductive material 207. In the embodiment, the size of the conductive structure 205 substantially equals to the size of the conductive material 207 (the conductive material 207 refers as the second surface 211 hereafter).

In the embodiment, the conductive structure 205, such as an under bump metallurgy structure comprising conductive multi-layer having adhesion, barrier, and wetting. Furthermore, the material of the conductive structure 205 depends on the material of the contacted conductive surface 203 or the contacted conductive material 207. In the embodiment, the conductive structure 205 is made of, but is not limited to, the composition including aluminum, vanadium/tin, and copper based layers. In a preferred embodiment, the conductive structure 205 contacts and is above the first surface 206. Compared with the first surface 206 of the conductive surface 203, the conductive structure 205 has an asymmetric shape. That is, compared with the first surface 206 of the conductive surface 203, two widths 212 and 213 from the edge of the first surface 206 to the edge of the conductive structure 205 are substantial not equal. It is noted that the substantial difference between the widths 212 and 213 is also adaptable on a symmetric structure, such as round structure.

Next, the conductive material 207, such as a conductive bump formed by any suitable method, is made of a lead-free based material, but is not limited to a lead-free based material. It is understandable that the size and position of the conductive material 207 are defined by the conductive structure 205. Thus, comparing to the first surface 206 of the conductive surface 203, the conductive material 207 also has an asymmetric shape.

Referring to the top-view diagram in FIG. 2, typically, corresponding to any one of horizontal axis 208 and vertical axis 209, the first surface 206 of the conductive surface 203 has a symmetric shape. That is, the horizontal axis 208 and vertical axis 209 divide the first surface 206 of the conductive surface 203 into two identical regions. In the embodiment, with respect to the vertical axis 209, the conductive structure 205 is not divided into the two equal regions by the vertical axis 209. In other words, corresponding to the vertical axis 209, the areas or widths on the two sides of the conductive structure 205 are not identical. Furthermore, alternatively, taking the shape of the conductive structure 205 as an example, the conductive structure 205 typically has a symmetric shape, such as circle. However, the conductive structure 205 in the embodiment has a geometric shape with a long/short axes, such as the width 215 wider than the width 214 in reference to the point “O”, but is not limited to a geometric shape with the width 215 wider than the width 214 in reference to the point “O”.

Accordingly, in the embodiment, the asymmetric-shaped UBM structure adopted is more robust than a conventional one. It is known that peering is usually generated between the UBM structure and the passivation layer. For a symmetric-shaped structure, the cracking occurs and progresses symmetrically on the two sides of the UBM, which causes a totally broken circuit. However, in contrast to the symmetric-shaped structure, the asymmetric-shaped structure aforementioned would prevent two regions from cracking symmetrically, which provides the wider or larger portion with a longer path of cracking propagation. That is, in contrast to a symmetric-shaped structure, the complete cracking on the asymmetric-shaped UBM structure occurs only on a single side so that the other side still can provide electrical connection. Moreover, the larger or wider the region is, the more the current is provided as well as heat dissipation and reliability, especially for the soldering between the chips on a printed circuit board.

Furthermore, the horizontal axis 208 and vertical axis 209 perpendicularly intersect at the geometric center “O” of the first surface 206 and are coplanar with the first surface 206. Similarly, the horizontal axis 208 and vertical axis 210 perpendicularly intersect at the geometric center “P” of the second surface 211 and are coplanar with the second surface 211 and the first surface 206. However, the widths 212 and 213 are substantially not so identical that the geometric centers of the first surface 206 and the second surface 211 are not overlapped. That is, the point “O” of the first surface 206 is on a vertical axis different from the one on which the point “P” of the second surface 211. It is noted that the first surface 206 especially and the second surface 211 are not limited to any sizes as long as the boundaries of the first surface 206 are within the ones of the second surface 211.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. An asymmetric bump structure applied on a wafer, wherein said wafer includes a plurality of chip units, each having an active surface, said asymmetric bump structure comprising:
a conductive surface on said active surface;
a conductive structure, positioned on both said conductive surface and said active surface wherein a portion of said conductive structure contacts a portion of said conductive surface; and
a conductive material contacting said conductive structure, wherein geometric centers of said portion of said conductive structure contacting said conductive surface and said conductive material are not on an identical vertical axis.

2. The asymmetric bump structure according to claim 1, wherein said conductive surface is provided by a metal pad contacted and positioned on said active surface.

3. The asymmetric bump structure according to claim 2, further comprising a passivation layer covering said active surface and a portion of said metal pad.

4. The asymmetric bump structure according to claim 1, wherein said conductive surface consists of a redistribution layer.

5. The asymmetric bump structure according to claim 1, wherein said conductive structure is an under bump metallurgy structure.

6. The asymmetric bump structure according to claim 5, wherein said under bump metallurgy structure is made of aluminum, vanadium and tin, and copper materials.

7. The asymmetric bump structure according to claim 1, wherein said conductive material is made of a lead-free based material.

8. The asymmetric bump structure according to claim 1, wherein said conductive material and said conductive structure are asymmetric.

9. An asymmetric bump structure, comprising:
a conductive pad having a first and a second surfaces, wherein said first surface has a geometric center;
a conductive structure contacting said first surface and positioned on both said first surface and a portion of said second surface; and
a conductive bump on said conductive structure, wherein a center of the surface of said conductive bump and said geometric center of said first surface are not on an identical vertical axis.

10. The asymmetric bump structure according to claim 9, further comprising a wafer including said conductive pad.

11. The asymmetric bump structure according to claim 9, wherein said conductive pad is an aluminum or copper pad.

12. The asymmetric bump structure according to claim 9, further comprising a passivation layer covering said second surface of said conductive pad.

13. The asymmetric bump structure according to claim 12, wherein said conductive structure further covers a portion of said passivation layer.

14. The asymmetric bump structure according to claim 9, wherein said conductive structure is an under bump metallurgy structure.

15. The asymmetric bump structure according to claim 14, wherein said under bump metallurgy structure is made of aluminum, vanadium and tin, and copper materials.
